(19) United States
(12) Patent Application Publication
(10) Pub. No.: US 2025/0309055 A1
(43) Pub. Date: Oct. 2, 2025

(54) TESTING STRUCTURES FOR MULTI-LEVEL TESTING OF SEMICONDUCTOR DEVICES

(71) Applicant: International Business Machines Corporation, Armonk, NY (US)

(72) Inventors: Nicholas Alexander Polomoff, Hopewell Junction, NY (US); Ruilong Xie, Niskayuna, NY (US); Brent A. Anderson, Jericho, VT (US); Haojun Zhang, Schenectady, NY (US); Lawrence Alfred Clevenger, Saratoga Springs, NY (US)

(21) Appl. No.: 18/620,542

(22) Filed: Mar. 28, 2024

(51) Int. Cl. H01L 23/48; H01L 21/66; H01L 23/528

(52) U.S. Cl. CPC H01L 23/481; H01L 22/32; H01L 23/5286

(57) ABSTRACT

A semiconductor test structure comprises a first side, a second side located opposite the first side, and a device layer disposed between the first side and the second side. The device layer comprises a plurality of devices. At least one first side wiring level is disposed on the first side, and at least one second side wiring level is disposed on the second side. Two or more of the plurality of devices are electrically connected to each other through at least one contact structure connecting the at least one first side wiring level and the at least one second side wiring level.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide techniques for forming semiconductor testing structures.

In one embodiment, a semiconductor test structure includes a first side, a second side located opposite the first side, and a device layer disposed between the first side and the second side. The device layer includes a plurality of devices. At least one first side wiring level is disposed on the first side, and at least one second side wiring level is disposed on the second side. Two or more of the plurality of devices are electrically connected to each other through at least one contact structure connecting the at least one first side wiring level and the at least one second side wiring level.

In another embodiment, a semiconductor test structure includes a plurality of first side wiring levels disposed on a first side of the semiconductor test structure, and a plurality of second side wiring levels disposed on a second side of the semiconductor test structure. The second side is located opposite the first side. A device layer is disposed between the first side and the second side, wherein the device layer includes a plurality of devices. The plurality of first side wiring levels and the plurality of second side wiring levels are serially connected through a plurality of contact structures. A subset of the plurality of contact structures includes a plurality of vias disposed through the device layer between the first side and the second side.

In another embodiment, a semiconductor test structure includes a first plurality of contact structures on a first side of a device layer including a plurality of devices, wherein respective ones of the first plurality of contact structures are connected to respective ones of the plurality of devices. The semiconductor test structure further includes a second plurality of contact structures on a second side of the device layer, wherein the second side of the device layer is located opposite the first side. The first plurality of contact structures are serially connected to the second plurality of contact structures through a plurality of vias disposed through the device layer.

These and other features and advantages of embodiments described herein will become more apparent from the accompanying drawings and the following detailed description.

### BRIEF DESCRIPTION OF THE DRAWINGS

FIG. 1A depicts a cross-sectional view of a semiconductor structure illustrating semiconductor sacrificial layers, channel layers and epitaxial layers for nanosheet transistors, according to an embodiment of the invention.

FIG. 1B depicts an enlarged view of a portion of FIG. 1A, according to an embodiment of the invention.

FIG. 2A depicts a cross-sectional view of a semiconductor structure following inter-layer dielectric (ILD) layer formation and planarization, dummy gate and sacrificial semiconductor layer removal, and replacement metal gate (RMG) formation, according to an embodiment of the invention.

FIG. 2B depicts an enlarged view of a portion of FIG. 2A, according to an embodiment of the invention.

FIG. 3 depicts a cross-sectional view of a semiconductor structure following middle-of-line (MOL) ILD deposition, MOL contact formation and BEOL wiring and via formation, and illustrating performance of electrical probe testing, according to an embodiment of the invention.

FIG. 4 depicts a cross-sectional view of a semiconductor structure following additional BEOL wiring and via formation, and illustrating performance of electrical probe testing, according to an embodiment of the invention.

FIG. 5 depicts a cross-sectional view of a semiconductor structure following carrier wafer bonding and wafer flipping, according to an embodiment of the invention.

FIG. 6 depicts a cross-sectional view of a semiconductor structure following semiconductor substrate removal, etch stop layer removal and additional semiconductor substrate removal, according to an embodiment of the invention.

FIG. 7 depicts a cross-sectional view of a semiconductor structure following backside ILD layer formation and backside ILD layer patterning for backside contacts, according to an embodiment of the invention.

FIG. 8 depicts a cross-sectional view of a semiconductor structure following backside contact and via formation, according to an embodiment of the invention.

FIG. 9 depicts a cross-sectional view of a semiconductor structure following backside wiring and via formation, according to an embodiment of the invention.

FIG. 10 depicts a cross-sectional view of a semiconductor structure following additional backside wiring and via formation, and illustrating performance of electrical probe testing, according to an embodiment of the invention.

FIG. 11 depicts a cross-sectional view of a semiconductor structure illustrating performance of additional electrical probe testing to isolate a problematic device, according to an embodiment of the invention.

FIG. 12 depicts a cross-sectional view of a semiconductor structure, according to another embodiment of the invention.

FIG. 13 depicts a cross-sectional view of a semiconductor structure, according to another embodiment of the invention.

### DETAILED DESCRIPTION

Illustrative embodiments of the invention may be described herein in the context of illustrative methods for forming semiconductor testing structures, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe), between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation stacked FET structures provide improved track height scaling, leading to structural gains (e.g., such as 30-40% structural gains for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including through the use of fin-shaped channels in FinFET devices, through the use of stacked nanosheet channels formed over a semiconductor substrate, and next-generation stacked FET devices.

Although embodiments of the present invention are discussed in connection with nanosheet stacks, the embodiments of the present invention are not necessarily limited thereto, and may similarly apply to nanowire stacks.

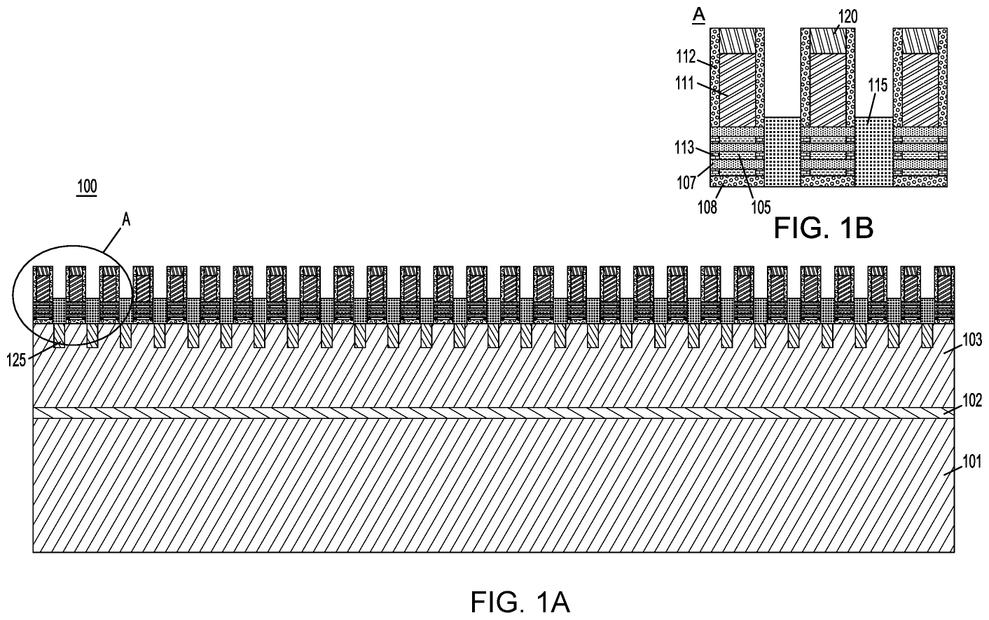

Referring to FIG. 1A and to FIG. 1B, which depicts an enlarged view of portion A in FIG. 1A, a semiconductor structure 100 includes a plurality of stacked nanosheet structures, each including a plurality of sacrificial layers 105 and a plurality of channel layers 107. In an illustrative embodiment, the sacrificial layers 105 include silicon germanium (SiGe) and the channel layers 107 include silicon. In illustrative embodiments, the sacrificial layers 105 include a germanium concentration of about 25% (e.g., SiGe25), but the embodiments are not necessarily limited to SiGe25 for the sacrificial layers 105. The lowermost sacrificial layer 105 of each nanosheet stack is formed on a bottom dielectric isolation (BDI) layer 108. The BDI layer 108 may include, for example, silicon oxide (SiOₓ) (where x is for example, 2, 1.99 or 2.01), silicon oxycarbide (SiOC), SiN, SiON, SiCN, BN, SiBCN, SiOCN or some other dielectric. The BDI layer 108 is under a bottom surface of the lowermost sacrificial layer 105.

First and second semiconductor substrates 101 and 103 include semiconductor material including, but not limited to, silicon (Si), III-V, II-V compound semiconductor materials or other like semiconductor materials. In addition, multiple layers of the semiconductor materials can be used as the semiconductor material of the first and second semiconductor substrates 101 and 103. An etch stop layer 102 is formed on the first semiconductor substrate 101, and may include, for example, silicon oxide (SiOₓ) (where x is for example, 2, 1.99 or 2.01), or SiGe. In illustrative embodiments, the etch stop layer 102 includes a germanium concentration of about 25% (e.g., SiGe25), but the embodiments are not necessarily limited to SiGe25 for the etch stop layer 102. The second semiconductor substrate 103 including, for example, the same semiconductor material as the first semiconductor substrate 101, or other like semiconductor material, is formed on the etch stop layer 102.

The sacrificial layers 105 and channel layers 107 are epitaxially grown in an alternating and stacked configuration. A first sacrificial layer 105 is followed by a first channel layer 107 on the first sacrificial layer 105, which is followed by a second sacrificial layer 105 on the first channel layer 107, and so on. As can be understood, the sacrificial and channel layers 105 and 107 are epitaxially grown from their corresponding underlying semiconductor layers.

While three sacrificial layers 105 and three channel layers 107 are shown, the embodiments of the present invention are not necessarily limited to the shown number of sacrificial and channel layers 105 and 107, and there may be more or less layers in the same alternating configuration depending on design constraints. The sacrificial layers 105, as described further herein, are eventually removed and replaced by gate structures.

Although SiGe is described as a sacrificial material for sacrificial layers 105, other materials can be used as long as the sacrificial layers 105 have the property of being able to be removed selectively compared to the material of the channel layers 107.

The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as a metal-organic chemical vapor deposition (MOCVD), rapid thermal chemical vapor deposition (RTCVD), ultra-high vacuum chemical vapor deposition (UHVCVD), or a low-pressure chemical vapor deposition (LPCVD) apparatus. A number of different sources may be used for the epitaxial deposition of the in situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane and combinations thereof. The temperature for epitaxial deposition typically ranges from 450° C. to 900° C. Although higher temperature typically results in faster deposition, the faster deposition may result in crystal defects and film cracking.

In a non-limiting illustrative embodiment, a height of the sacrificial layers 105 can be in the range of about 6 nm to about 15 nm depending on the application of the device. Also, in a non-limiting illustrative embodiment, a height of the channel layers 107 can be in the range of about 6 nm to about 15 nm depending on the desired process and application. In accordance with an embodiment of the present invention, each of the channel layers 107 has the same or substantially the same composition and size as each other, and each of the sacrificial layers 105 has the same or substantially the same composition and size as each other.

As used herein, “frontside or “first side” refers to a side on top of the first and/or second semiconductor substrates 101 and 103 and/or in front of, on top of or in an upward direction from the stacked nanosheet/gate and channel layers of the transistors in the orientation shown in the cross-sectional figures. As used herein, “backside” or “second side” refers to a side below the first and/or second semiconductor substrates 101 and 103 and/or behind, below or in a downward direction from the stacked nanosheet/gate and channel layers of the transistors in the orientation shown in the cross-sectional figures (e.g., opposite the “frontside”).

Dummy gate portions 111 are formed on the uppermost channel layer 107 and, although not shown, around the stacked nanosheet configurations of the sacrificial layers 105 and channel layers 107. The dummy gate portions 111 include, but are not necessarily limited to, an amorphous silicon (a-Si) layer. The dummy gate portions 111 are deposited using deposition techniques such as, for example, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD), sputtering and/or plating, followed by a planarization process, such as, chemical mechanical planarization (CMP), and lithography and etching steps to remove excess dummy gate material, and pattern the deposited layer. Hardmask layers 120 are formed on the dummy gate portions 111. The hardmask layers 120 include, for example, a nitride such as silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN), combinations thereof or other nitride material.

Gate spacers 112 are formed on sides of the hardmask layers 120 and dummy gate portions 111 by one or more of the deposition techniques noted in connection with deposition of the dummy gate material. The spacer material can include for example, one or more dielectrics, including, but not necessarily limited to, SiN, SiON, SiOC, SiCN, BN, SiBN, SiBCN, SiOCN, SiOₓ, and combinations thereof. According to an embodiment, the hardmask layers 120 and gate spacers 112 can be the same material or different materials. The gate spacers 112 can be formed by any suitable techniques such as deposition followed by directional etching. Deposition may include, but is not limited to, ALD or CVD. Directional etching may include but is not limited to, reactive ion etching (RIE).

Due to, for example, germanium in the sacrificial layers 105, lateral etching of the sacrificial layers 105 can be performed selective to the channel layers 107, such that the side portions of the sacrificial layers 105 can be removed to create vacant areas to be filled in by inner spacers 113. The material of the inner spacers 113 can include, but is not necessarily limited to, a nitride, such as, SiN, SiON, SiCN, BN, SiBN, SiBCN or SiOCN. Gate spacers 112 are positioned on the nanosheet stacks on opposite lateral sides of the dummy gate portions 111. In an illustrative embodiment, the gate spacers 112 are formed from the same or similar material to that of the inner spacers 113. Like the gate spacers 112, the inner spacers 113 can be formed by any suitable techniques such as deposition followed by directional etching.

Prior to formation of source/drain regions 115, portions of the second semiconductor substrate 103 are removed, such that portions of the second semiconductor substrate 103 are recessed to create openings (e.g., “trenches”) in the second semiconductor substrate 103. Sacrificial placeholder layers 125 for backside source/drain contacts are formed in the trenches. In more detail, sacrificial placeholder layers 125 including, for example, SiGe, III-V semiconductor material or other semiconductor material are epitaxially grown in the trenches.

Following formation of the sacrificial placeholder layers 125, source/drain regions 115 are grown from the sides of the channel layers 107. In addition, growth of the source/drain regions 115 may also occur from the sacrificial placeholder layers 125. As can be seen, the source/drain regions 115 are formed on the sacrificial placeholder layers 125. Side surfaces of respective ones of the channel layers 107 contact a side surface at least one adjacent source/drain region 115. The top surfaces of the source/drain regions 115 are above the top surfaces of uppermost ones of the channel layers 107.

According to a non-limiting embodiment of the present invention, the conditions of the epitaxial growth process for the source/drain regions 115 are, for example, RTCVD epitaxial growth using SiH₄, SiH₂Cl₂, GeH₄, CH₃SiH₃, B₂H₆, PF₃, and/or H₂ gases with temperature and pressure ranges of about 450° C. to about 800° C., and about 5 Torr-about 300 Torr. In the case of n-type FETS (nFETs), the source/drain regions 115 can include silicon doped with n-type dopants including, for example, phosphorus (P), arsenic (As) and antimony (Sb). In the case of p-type FETS (pFETs), the source/drain regions 115 can include silicon doped with p-type dopants including, for example, boron (B), boron fluoride (BF₂), gallium (Ga), indium (In), and thallium (TI).

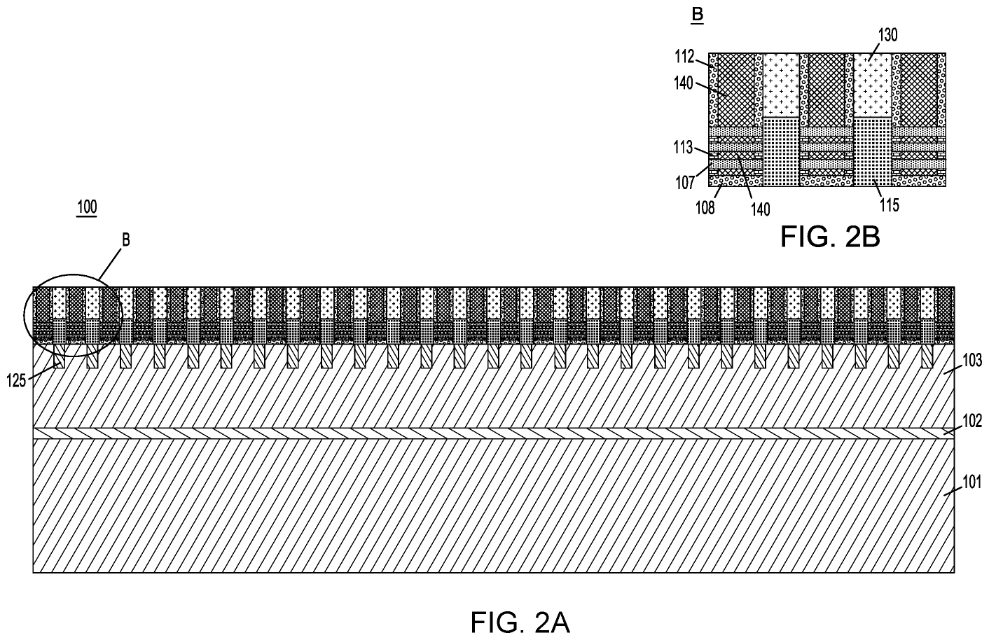

Referring to FIG. 2A and to FIG. 2B, which depicts an enlarged view of portion B in FIG. 2A, an inter-layer dielectric (ILD) layer 130 is deposited to fill in portions on and around the source/drain regions 115. The ILD layer 130 is deposited using deposition techniques such as, for example, CVD, PECVD, RFCVD, PVD, ALD, MBD, PLD, and/or LSMCD, followed by a planarization process, such as CMP to remove excess portions of the ILD layer 130 deposited on top of the hardmask layers 120 and gate spacers 112, and to remove the hardmask layers 120 and portions of the gate spacers 112 to expose the dummy gate portions 111. The ILD layer 130 may include, for example, SiOₓ, SiOC, SiOCN or some other dielectric.

The dummy gate portions 111 are selectively removed to create vacant areas where gate structures will be formed in place of the dummy gate portions 111. The selective removal can be performed using, for example, hot ammonia to remove a-Si. In addition, the sacrificial layers 105 are selectively removed to create vacant areas where gate structures will be formed in place of the sacrificial layers 105. The sacrificial layers 105 are selectively removed with respect to the channel layers 107. The selective removal can be performed using, for example, a dry HCl etch.

Following removal of the dummy gate portions 111 and sacrificial layers 105, the channel layers 107 are suspended, and gate regions 140, including, for example, gate and dielectric portions are formed in the vacant portions left by removal of the dummy gate portions 111, and the sacrificial layers 105. In illustrative embodiments, each gate region 140 includes a gate dielectric layer such as, for example, a high-K dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. According to an embodiment, the gate regions 140 each include a metal gate portion including a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The metal gate portions can also each further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for the metal gate portions as desired.

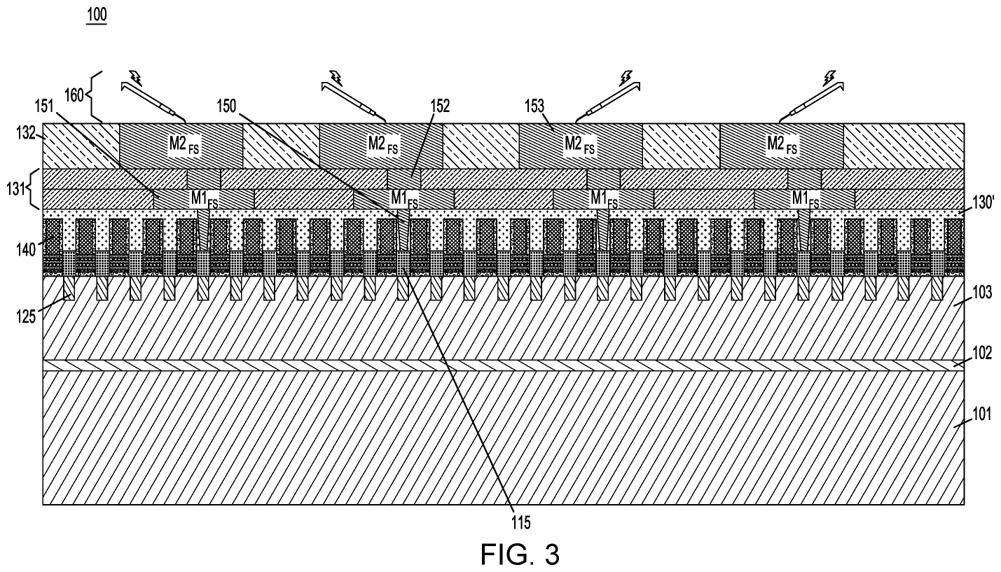

Referring to FIG. 3, additional ILD material is deposited to form an additional ILD layer 130′ on top of the ILD layer 130. The additional ILD layer 130′ is deposited using the same or similar deposition techniques and includes the same or similar material to that of the ILD layer 130. Parts of the additional ILD layer 130′ and ILD layer 130 are removed to form trenches through the additional ILD layer 130′ and ILD layer 130 exposing portions of multiple ones of the source/drain regions 115 (in this case, four of the source/drain regions 115). Frontside source/drain contacts 150 to the multiple ones of the source/drain regions 115 are formed in the trenches in the additional ILD layer 130′ and the ILD layer 130. According to an embodiment, masks are formed on parts of the additional ILD layer 130′, and exposed portions of the additional ILD layer 130′ and ILD layer 130 corresponding to where the trenches are to be formed are removed using, for example, a dry etching process using a RIE or ion beam etch (IBE) process, a wet chemical etch process or a combination of these etching processes. A dry etch may be performed using a plasma. Such wet or dry etch processes include, for example, IBE by Ar/CHF3 based chemistry.

Metal layers are deposited in the trenches to form the frontside source/drain contacts 150. The metal layers include, for example, a silicide layer, such as Ni, Ti, NiPt, etc., a metal adhesion layer, such as TiN, and a conductive metal fill layer, such as Cu, W, Al, Co, Ru, etc., and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the additional ILD layer 130′. In some embodiments, the silicide layer and/or metal adhesion layer can be omitted.

The frontside source/drain contacts 150 contact respective ones of the source/drain regions 115. The frontside source/drain contacts 150 extend through the additional ILD layer 130′ and ILD layer 130 to land on and contact the corresponding source/drain regions 115.

Following formation of the frontside source/drain contacts 150, multiple ones of first and second dielectric layers 131 and 132, which may include different materials, are deposited on the additional ILD layer 130′. As shown in FIG. 3, first and second BEOL contacts 151 and 153 are formed in the first and second dielectric layers 131 and 132. The first and second BEOL contacts 151 and 153 in each metallization level (e.g., M1_{FS} and M2_{FS}) form first and second frontside wiring levels (also referred to herein as first and second frontside metallization levels M1_{FS} and M2_{FS}). Each wiring level includes BEOL contacts (e.g., first BEOL contacts 151 or second BEOL contacts 153) which are physically separated from each other by portions of the first or second dielectric layers 131 or 132. Respective first vias 152 connect respective pairs of first and second BEOL contacts 151 and 153. Similar to the frontside source/drain contacts 150, the first and second BEOL contacts 151 and 153 and first vias 152 are formed by opening trenches in the first and second dielectric layers 131 and 132 and filling the trenches with metal layers.

As can be seen in FIG. 3, at an intermediate stage of the semiconductor fabrication process, electrical probes 160 contacting respective ones of the second BEOL contacts 153 in the second frontside metallization level M2_{FS} (second frontside wiring level) can apply voltages to the respective ones of the second BEOL contacts 153 in order to individually test corresponding transistors to which the underlying frontside source/drain contacts 150 are connected. Connections to the underlying source/drain regions 115 made by respective combinations of first and second BEOL contacts 151 and 153 and first vias 152 can also be tested.

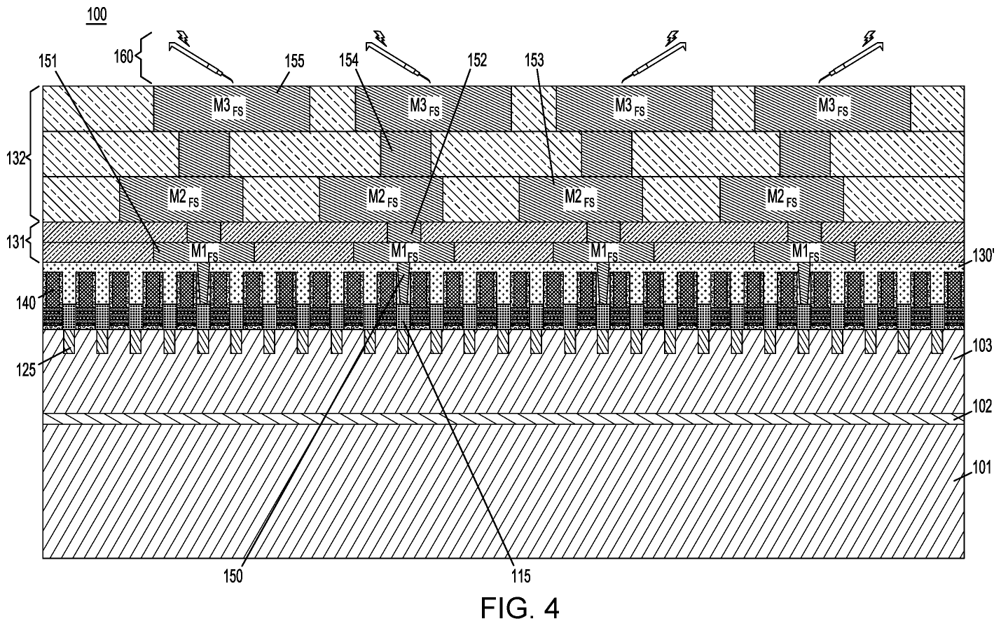

Referring to FIG. 4, similar to what is shown in FIG. 3, additional second dielectric layers 132 are formed on the semiconductor structure 100 from FIG. 3. Third BEOL contacts 155 and second vias 154 connecting the third BEOL contacts 155 to the second BEOL contacts 153 are formed in the additional second dielectric layers 132. The third BEOL contacts 155 in the third metallization level (e.g., M3_{FS}) form a third frontside wiring level (also referred to herein as third frontside metallization level M3_{FS}). The third frontside wiring level, like the first and second frontside wiring levels includes BEOL contacts (e.g., third BEOL contacts 155) which are physically separated from each other by portions of the additional second dielectric layers 132. Respective second vias 154 connect respective pairs of second and third BEOL contacts 153 and 155. Similar to the first and second BEOL contacts 151 and 153 and first vias 152, the third BEOL contacts 155 and the second vias 154 are formed by opening trenches in the additional second dielectric layers 132 and filling the trenches with metal layers.

As can be seen in FIG. 4, at an intermediate stage of the semiconductor fabrication process, electrical probes 160 contacting respective ones of the third BEOL contacts 155 in the third frontside metallization level M3_{FS} (third frontside wiring level) can apply voltages to the respective ones of the third BEOL contacts 155 in order to individually test corresponding transistors to which the underlying frontside source/drain contacts 150 are connected. Connections to the underlying source/drain regions 115 made by respective combinations of first, second and third BEOL contacts 151, 153 and 155 and first and second vias 152 and 154 can also be tested.

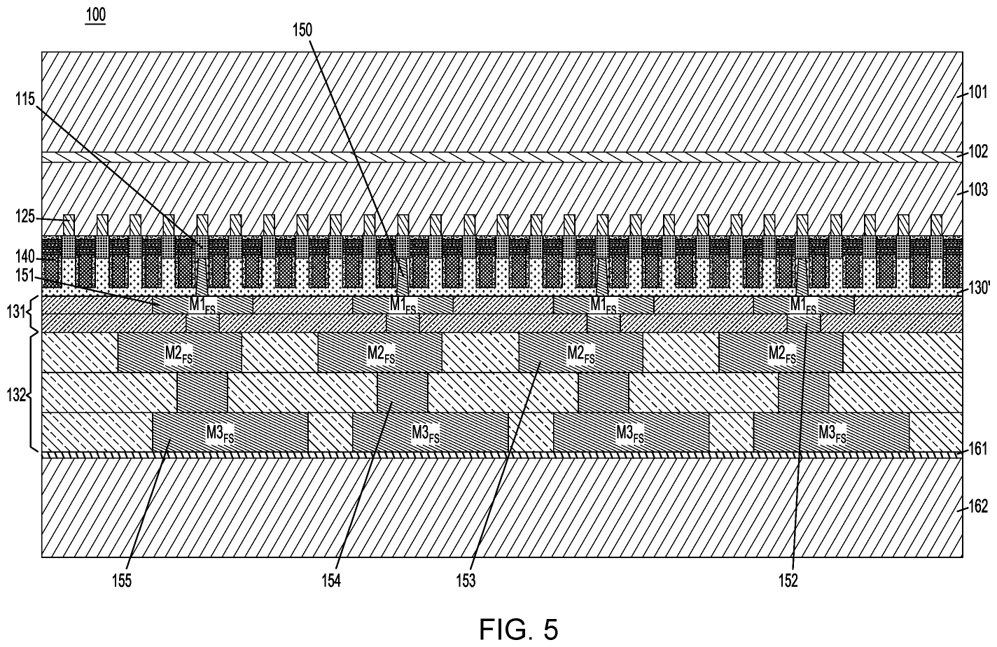

Referring to FIG. 5, a carrier wafer 162 is bonded to the third frontside metallization level M3_{FS} (third frontside wiring level) by, for example, a dielectric bonding layer 161. The dielectric bonding layer 161 includes, for example, an oxide such as, for example, tetraethyl orthosilicate (TEOS), SiN, SiCN or another dielectric. The carrier wafer 162 may be formed of materials similar to that of the first semiconductor substrate 101, and may be formed over the third frontside metallization level M3_{FS} (third frontside wiring level) including the third BEOL contacts 155 using a wafer bonding process, such as dielectric-to-dielectric bonding.

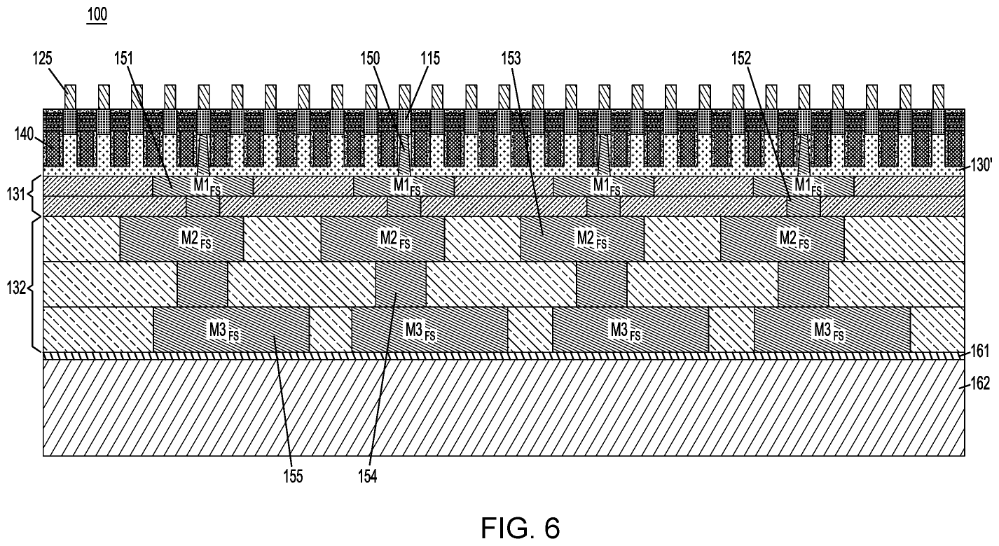

Using the carrier wafer 162, the semiconductor structure 100 is “flipped” (e.g., rotated 180 degrees) so that the structure is inverted. Referring to FIG. 6, the first semiconductor substrate 101 is removed from the backside of the semiconductor structure 100. The removal process, which includes etching of the first semiconductor substrate 101, stops at the etch stop layer 102. For example, the first semiconductor substrate 101 is selectively etched with an etchant that selectively etches silicon with respect to a material of the etch stop layer 102 (e.g., SiGe). The etch stop layer 102 and the second semiconductor substrate 103 (e.g., silicon layer) are selectively removed from the semiconductor structure 100 with respect to the sacrificial placeholder layers 125 and the BDI layers 108. The etch stop layer 102 is removed, followed by removal of the second semiconductor substrate 103. The BDI layers 108 and the sacrificial placeholder layers 125 are exposed. Etching processes for removal of the etch stop layer 102 include, for example, IBE by Ar/CHF3 based chemistry.

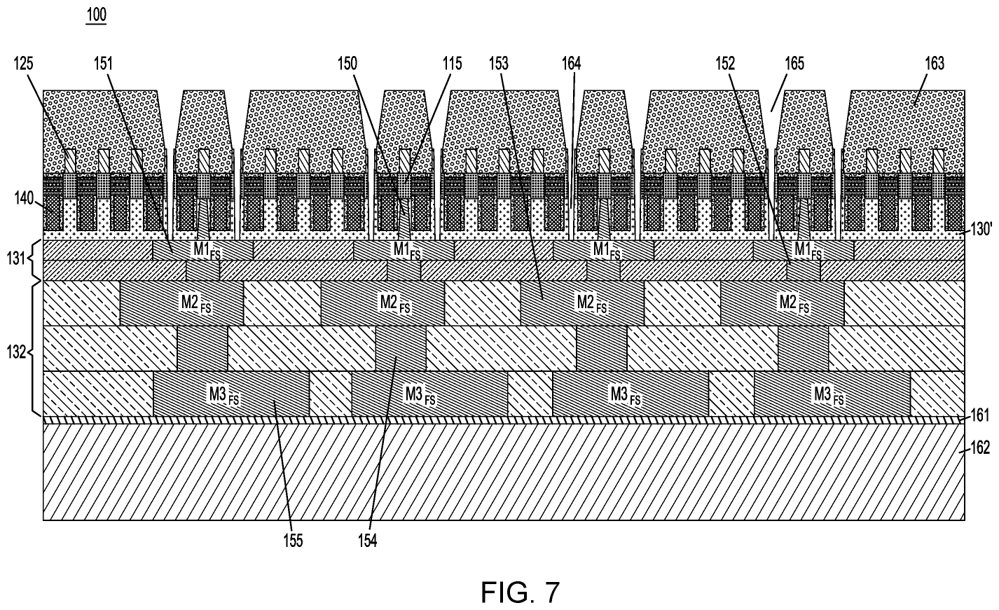

Referring to FIG. 7, a backside ILD layer 163 is deposited to fill in areas formerly occupied by the etch stop layer 102 and the second semiconductor substrate 103. The backside ILD layer 163 is deposited using deposition techniques such as, for example, CVD, PECVD, RFCVD, PVD, ALD, MBD, PLD, and/or LSMCD, followed by a planarization process, such as, CMP. The backside ILD layer 163 may include, for example, SiOₓ, SiOC, SiOCN or some other dielectric.

Parts of backside ILD layer 163, underlying parts of some of the sacrificial placeholder layers 125, underlying parts of some of the source/drain regions 115 and underlying parts of the additional ILD layer 130′ are removed to form trenches including backside source/drain contact openings 165 and deep via openings 164 through the backside ILD layer 163, through designated ones of the sacrificial placeholder layers 125, through designated ones of the source/drain regions 115 and through portions of the additional ILD layer 130′. The trenches including the backside source/drain contact openings 165 and deep via openings 164 expose surfaces of corresponding first BEOL contacts 151.

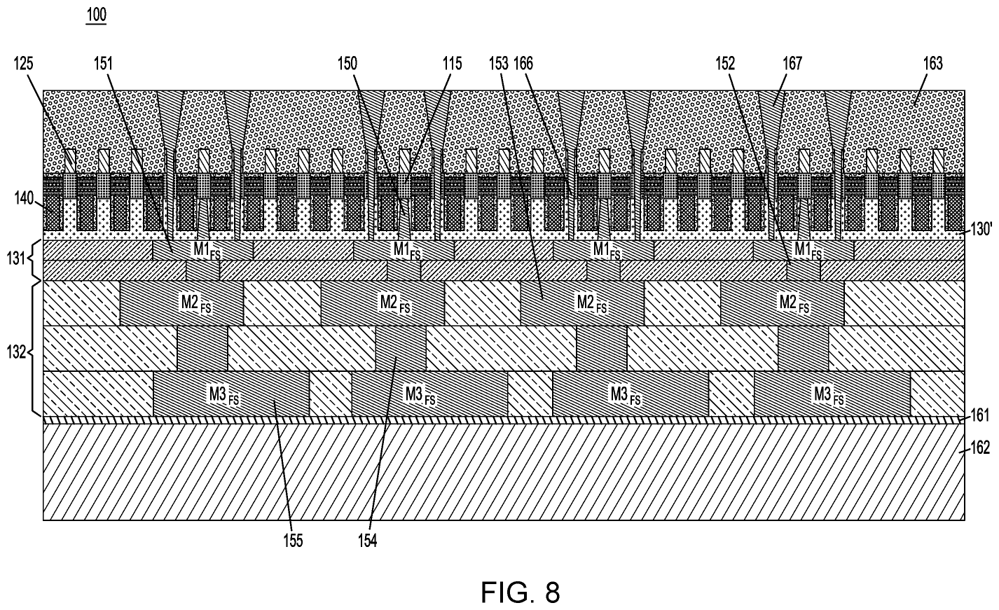

According to an embodiment, masks are formed on parts of the backside ILD layer 163. Referring to FIG. 8, exposed portions of the backside ILD layer 163, corresponding to where backside source/drain contacts 167 and deep vias 166 are to be formed, are removed using, for example, a dry etching process using a RIE or IBE process, a wet chemical etch process or a combination of these etching processes. A dry etch may be performed using a plasma. Such wet or dry etch processes include, for example, IBE by Ar/CHF3 based chemistry.

The backside source/drain contacts 167 are formed in the backside ILD layer 163 in the backside source/drain contact openings 165. The deep vias 166 are formed in the deep via openings 164 through the backside ILD layer 163, through remaining portions of the designated sacrificial placeholder layers 125, through remaining portions of the designated source/drain regions 115 and through the additional ILD layer 130′ to land on and contact the exposed surfaces of the corresponding first BEOL contacts 151. Metal layers are deposited in the backside source/drain contact openings 165 and the deep via openings 164 to form the backside source/drain contacts 167 and the deep vias 166. The metal layers include, for example, a silicide layer, such as Ni, Ti, NiPt, etc., a metal adhesion layer, such as TiN, and a conductive metal fill layer, such as Cu, W, Al, Co, Ru, etc., and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the backside ILD layer 163. In some embodiments, the silicide layer and/or metal adhesion layer can be omitted.

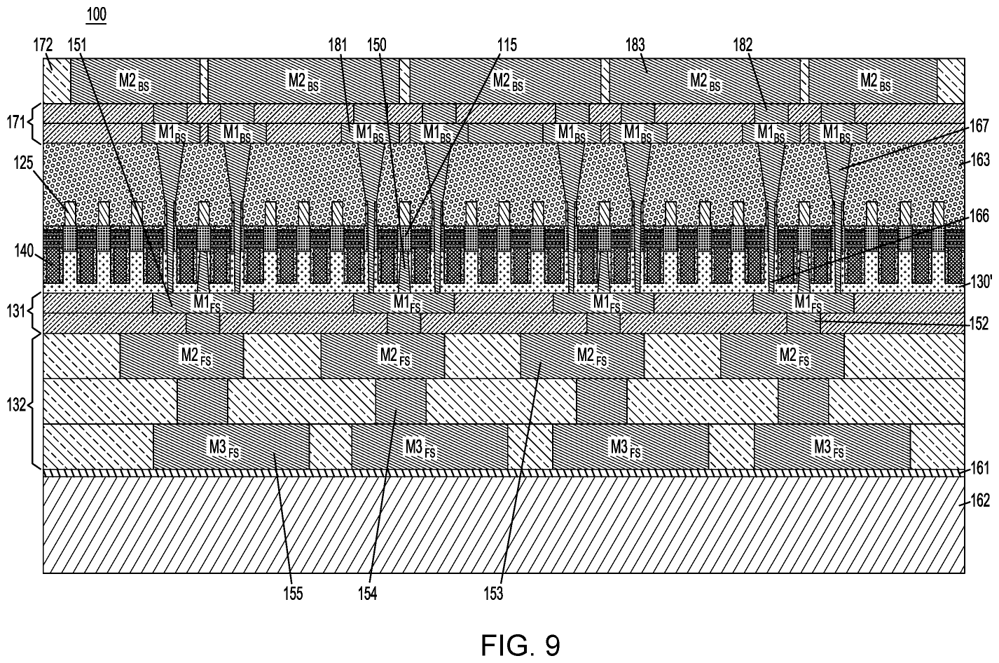

Referring to FIG. 9, following formation of the backside source/drain contacts 167 and the deep vias 166, multiple ones of first and second backside dielectric layers 171 and 172, which may include different materials, are deposited on the backside ILD layer 163. As shown in FIG. 9, first and second backside contacts 181 and 183 are formed in the first and second backside dielectric layers 171 and 172. The first and second backside contacts 181 and 183 in each metallization level (e.g., M1_{BS} and M2_{BS}) form first and second backside wiring levels (also referred to herein as first and second backside metallization levels M1_{BS} and M2_{BS}). Each wiring level includes backside contacts (e.g., first backside contacts 181 or second backside contacts 183) which are physically separated from each other by portions of the first or second backside dielectric layers 171 or 172. Respective first vias 182 connect various pairs of first and second backside contacts 181 and 183. As can be seen, some of the second backside contacts 183 are respectively connected to two different second backside contacts 183. The first and second backside contacts 181 and 183 and first vias 182 are formed by opening trenches in the first and second backside dielectric layers 171 and 172 and filling the trenches with metal layers.

As shown in FIG. 9, the second backside contact 183 in the upper left portion of FIG. 9 is serially connected to the second backside contact 183 in the upper right portion of FIG. 9 through the first and second backside contacts 181 and 183 of the first and second backside wiring levels (e.g., first and second backside metallization levels M1_{BS} and M2_{BS}), the first vias 182, the backside source/drain contacts 167, the deep vias 166, and the first BEOL contacts 151 of the first frontside wiring level (e.g., first frontside metallization level M1_{FS}). As can be understood, the continuous connections extend between the backside and the frontside of the semiconductor structure 100 through the deep vias 166 which connect the backside contacts and the frontside contacts. As can be seen in FIG. 9, all of the contacts (e.g., 150, 151, 153, 155, 181, 183 and vias 152, 154, 166, 182) in the semiconductor structure are serially connected even though they may be physically separated from each other by one or more dielectric layers in the horizontal direction in the cross-sectional views.

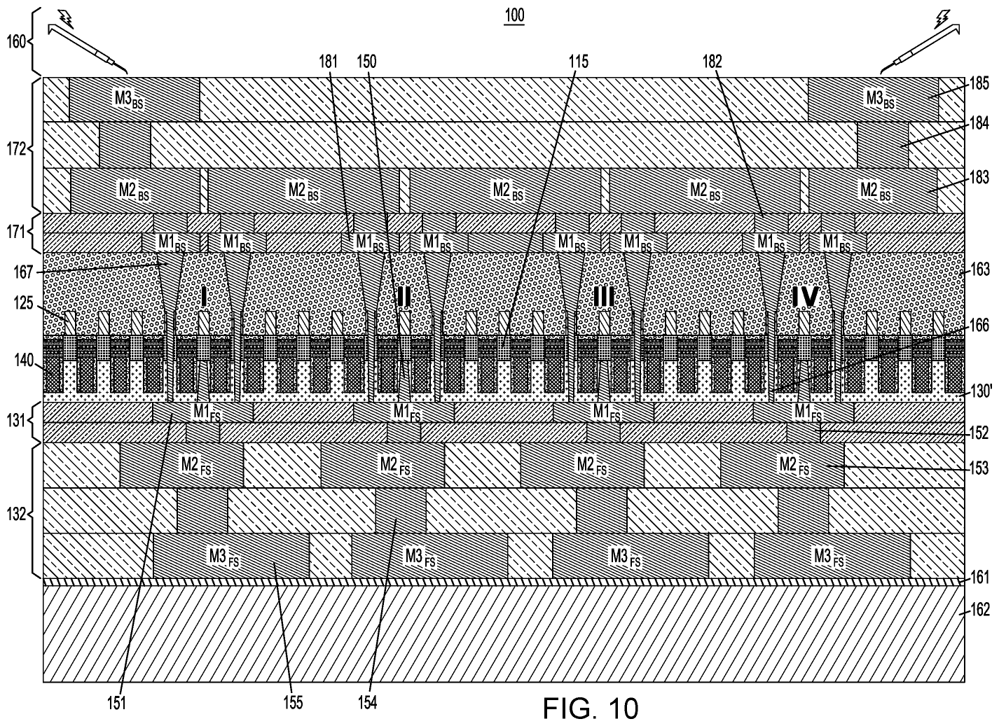

Referring to FIG. 10, similar to what is shown in FIG. 9, additional second backside dielectric layers 172 are formed on the semiconductor structure 100 from FIG. 9. Third backside contacts 185 and second vias 184 connecting the third backside contacts 185 to second backside contacts 183 are formed in the additional second backside dielectric layers 172. The third backside contacts 185 in the third metallization level (e.g., M3_{BS}) form a third backside wiring level (also referred to herein as third backside metallization level M3_{BS}). The third backside wiring level, like the first and second backside wiring levels includes backside contacts (e.g., third backside contacts 185) which are physically separated from each other by portions of the additional second backside dielectric layers 172. Respective second vias 184 connect respective pairs of second and third backside contacts 183 and 185. Similar to the first and second backside contacts 181 and 183 and first vias 182, the third backside contacts 185 and the second vias 184 are formed by opening trenches in the second backside dielectric layers 172 and filling the trenches with metal layers.

As shown in FIG. 10, the third backside contact 185 in the upper left portion of FIG. 10 is serially connected to the third backside contact 185 in the upper right portion of FIG. 10 through the first and second backside contacts 181 and 183 of the first and second backside wiring levels (e.g., first and second backside metallization levels M1_{BS} and M2_{BS}), the first and second vias 182 and 184, the backside source/drain contacts 167, the deep vias 166, and the first BEOL contacts 151 of the first frontside wiring level (e.g., first frontside metallization level MIFs). As can be understood, the continuous connections extend between the backside and the frontside of the semiconductor structure 100 through the deep vias 166 which connect the backside contacts and the frontside contacts. As can be seen in FIG. 10, all of the contacts (e.g., 150, 151, 153, 155, 181, 183, 185 and vias 152, 154, 166, 182, 184) in the semiconductor structure are serially connected even though they may be physically separated from each other by one or more dielectric layers in the horizontal direction in the cross-sectional views.

As can be seen in FIG. 10, by virtue of the serial connection of the contacts and devices I, II, III and IV, the electrical probe 160 contacting the third backside contact 185 in the upper left portion of FIG. 10 can apply a voltage to the third backside contact 185 in the upper left portion of FIG. 10 to test each of devices I, II, III and IV and generate an output voltage to be read by the electrical probe 160 contacting the third backside contact 185 in the upper right portion of FIG. 10. Conversely, by virtue of the serial connection, the electrical probe 160 contacting the third backside contact 185 in the upper right portion of FIG. 10 can apply a voltage to the third backside contact 185 in the upper right portion of FIG. 10 to test each of devices I, II, III and IV and generate an output voltage to be read by the electrical probe 160 contacting the third backside contact 185 in the upper left portion of FIG. 10. If the output voltage is within a designated acceptable range, the devices I, II, III and IV and/or the contacts can be determined to be in proper working order. If the output voltage is not within a designated acceptable range, at least one of the devices I, II, III and IV and/or at least one of the contacts can be determined to not be in proper working order.

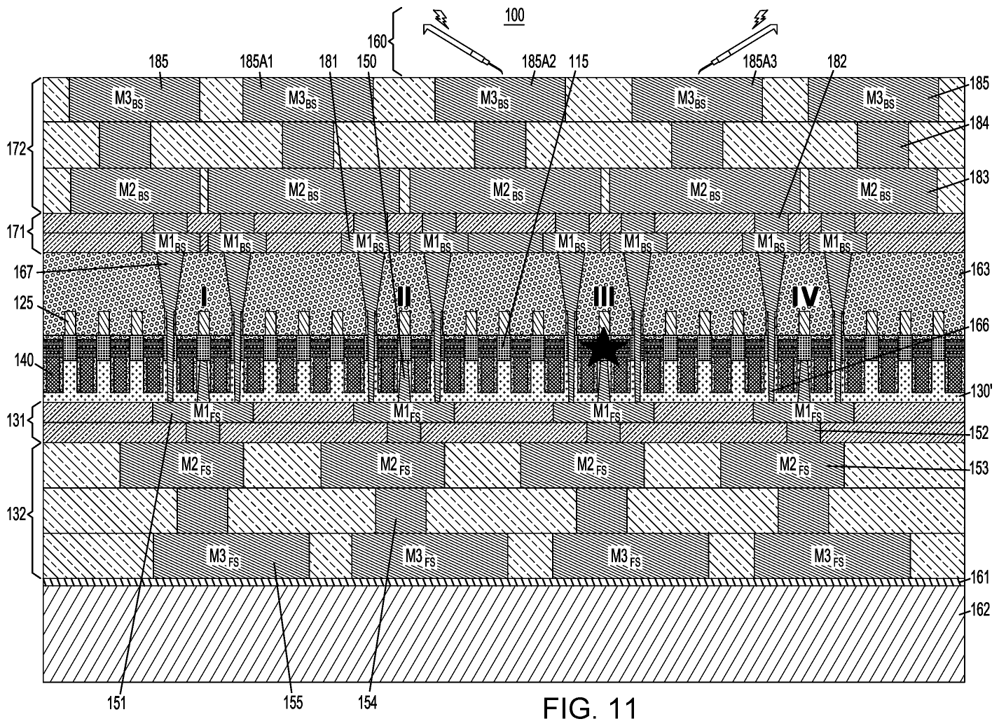

Referring to FIG. 11, given the serial connection of the contacts and devices I, II, III and IV, by adding first, second and third additional third backside contacts 185A1, 185A2 and 185A3 and corresponding underlying second vias 184 for electrical probes 160 to the semiconductor structure 100, additional electrical probe testing can be performed to isolate a problematic device and/or contact. For example, assuming there is an output voltage at one of the third backside contacts 185 (e.g., third backside contacts 185 in upper left and right corners of FIG. 11) that is not within a designated acceptable range, it can be difficult to determine which of the devices I, II, III or IV are causing the problematic output. Output voltages at respective ones of the first, second and third additional third backside contacts 185A1, 185A2 and 185A3 can be tested to determine if a device is faulty. For example, assuming an input voltage is applied by an electrical probe 160 at the third backside contact 185 in the upper left portion of FIG. 11, if the output voltage is not within an acceptable range at the third backside contact 185 in the upper right portion of FIG. 11, then it can be any of devices I, II, III and IV that may be causing the issue. If the output is within an acceptable range at first and second additional third backside contacts 185A1 and 185A2, then a determination can be made that devices I and II are operating properly. In addition, if an input voltage is applied by an electrical probe 160 at the third additional third backside contact 185A3 and the output voltage is within an acceptable range at the third backside contact 185 in the upper right portion of FIG. 11, then it can be concluded that device IV is operating properly. However, as shown in FIG. 11, if an input voltage is applied by an electrical probe 160 at the second additional third backside contact 185A2 and the output voltage is not within an acceptable range at the third additional third backside contact 185A3 (or vice versa), then it can be concluded that device III is the problematic device (as shown by the star in FIG. 11).

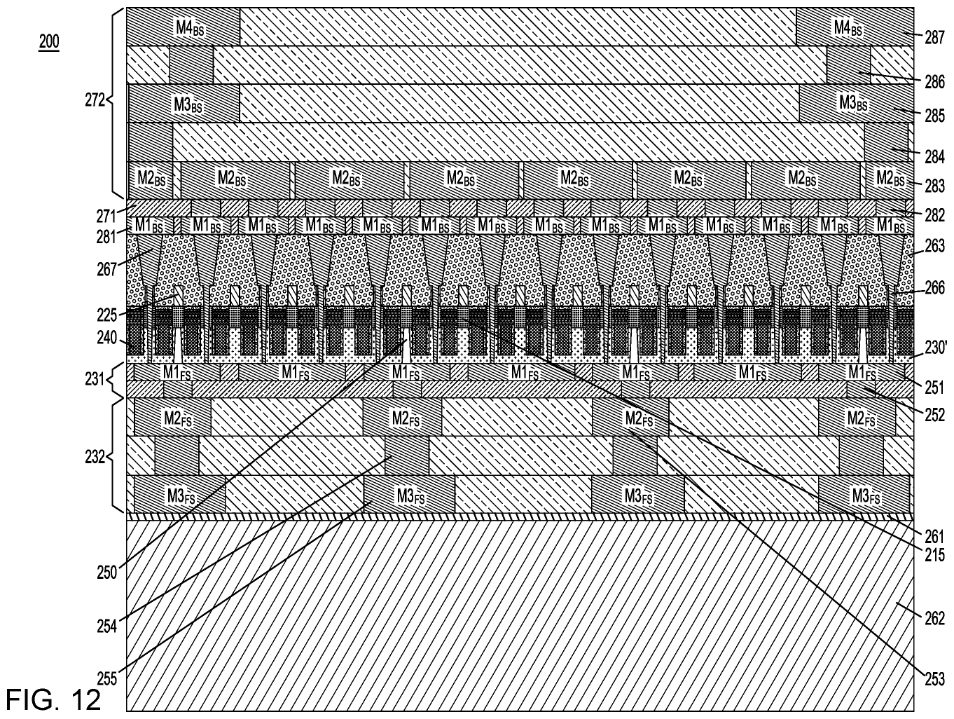

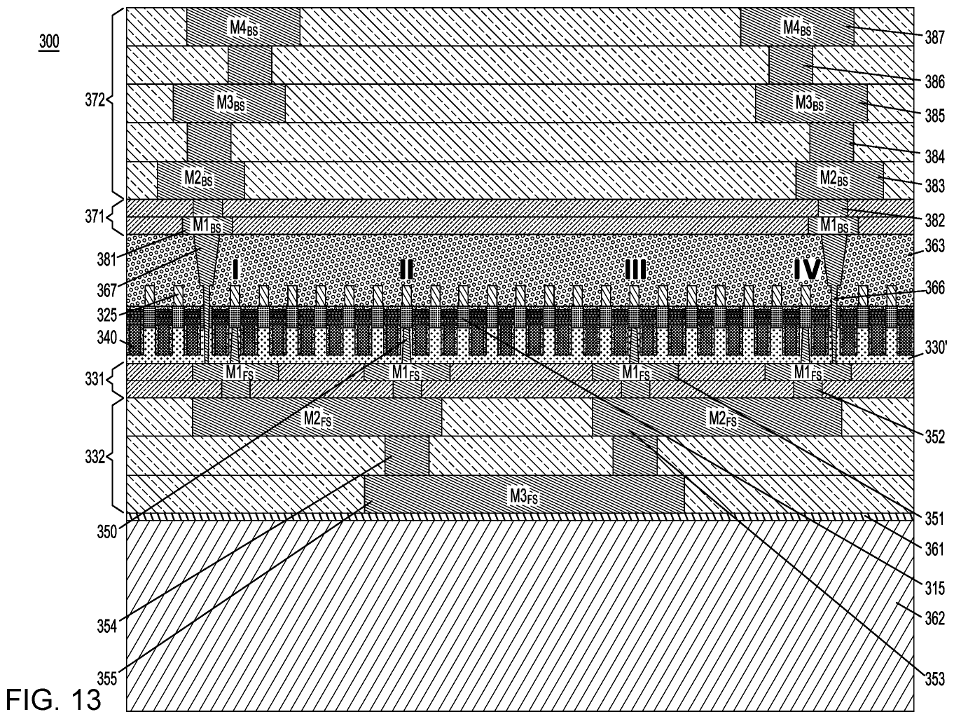

FIGS. 12 and 13 depict cross-sectional views of semiconductor structures 200 and 300, according to other embodiments of the invention. The semiconductor structures 200 and 300 are similar to the semiconductor structure 100 described in connection with FIGS. 1-11, except that the configurations of the contacts differ. For example, in the semiconductor structures 200 and 300, the device layers are similar to that in the semiconductor structure 100, including nanosheet transistors with gate regions 240 and 340 like the gate regions 140, source/drain regions 215 and 315 like the source/drain regions 115 and additional ILD layers 230′ and 330′ like the additional ILD layer 130′. Also like the semiconductor structure 100, the semiconductor structures 200 and 300 include carrier wafers 262/362 and dielectric bonding layers 261/361, like the carrier wafer 162 and dielectric bonding layer 161, backside ILD layers 263/363, like the backside ILD layer 163, first dielectric layers 231/331 and second dielectric layers 232/332, like the first and second dielectric layers 131 and 132, first backside dielectric layers 271/371 and second backside dielectric layers 272/372, like the first and second backside dielectric layers 171 and 172, and sacrificial placeholder layers 225/325 like the sacrificial placeholder layers 125.

The semiconductor structures 200 and 300 further include frontside source/drain contacts 250/350, which are like the frontside source/drain contacts 150, but in different locations and/or configurations. The semiconductor structures 200 and 300 also include backside source/drain contacts 267/367 and deep vias 266/366, which are like the backside source/drain contacts 167 and deep vias 166, but in different locations, numbers and/or configurations.

Like the semiconductor structure 100, the semiconductor structures 200 and 300 include three frontside wiring (metallization) levels (e.g., M1_{FS}, M2_{FS}, M3_{FS}) with first, second and third BEOL contacts 251/351, 253/353 and 255/355, like the first, second and third BEOL contacts 151, 153 and 155, and first and second vias 252/352 and 254/354, like the first and second vias 152 and 154. The location, number and/or configuration of first, second and third BEOL contacts 251/351, 253/353 and 255/355, and of the first and second vias 252/352 and 254/354 differs from those of the semiconductor structure 100.

Like the semiconductor structure 100, the semiconductor structures 200 and 300 include backside wiring (metallization) levels (e.g., M1_{BS}, M2_{BS}, M3_{BS}) with first, second and third backside contacts 281/381, 283/383 and 285/385, like the first, second and third backside contacts 181, 183 and 185, and first and second vias 282/382 and 284/384, like the first and second vias 182 and 184. The location, number and/or configuration of first, second and third backside contacts 281/381, 283/383 and 285/385, and of the first and second vias 282/382 and 284/384 differs from those of the semiconductor structure 100. In addition, unlike the semiconductor structure 100, the semiconductor structures 200 and 300 further include an additional (fourth) backside wiring (metallization) level (e.g., M4_{BS}) with fourth backside contacts 287/387. Third vias 286/386 connect the fourth backside contacts 287/387 with third backside contacts 285/385.

As shown in FIG. 12, the fourth backside contact 287 in the upper left portion of FIG. 12 is serially connected to the fourth backside contact 287 in the upper right portion of FIG. 12 through the first, second and third backside contacts 281, 283 and 285 of the first, second and third backside wiring levels (e.g., first, second and third backside metallization levels M1_{BS}, M2_{BS} and M3_{BS}), the first, second and third vias 282, 284 and 286, the backside source/drain contacts 267, the deep vias 266, and the first BEOL contacts 251 of the first frontside wiring level (e.g., first frontside metallization level MIFs). As can be understood, the continuous connections extend between the backside and the frontside of the semiconductor structure 200 through the deep vias 266 which connect the backside contacts and the frontside contacts. As can be seen in FIG. 12, all of the contacts (e.g., 250, 251, 253, 255, 281, 283, 285, 287 and vias 252, 254, 266, 282, 284, 286) in the semiconductor structure 200 are serially connected even though they may be physically separated from each other by one or more dielectric layers in the horizontal direction in the cross-sectional views.

As can be seen in FIG. 12, by virtue of the serial connection of the contacts and devices, an electrical probe contacting the fourth backside contact 287 in the upper left portion of FIG. 12 can apply a voltage to the fourth backside contact 287 in the upper left portion of FIG. 12 to test each of the connected devices and generate an output voltage to be read by an electrical probe contacting the fourth backside contact 287 in the upper right portion of FIG. 12. Conversely, by virtue of the serial connection, an electrical probe contacting the fourth backside contact 287 in the upper right portion of FIG. 12 can apply a voltage to the fourth backside contact 287 in the upper right portion of FIG. 12 to test each of the connected devices and generate an output voltage to be read by the electrical probe contacting the fourth backside contact 287 in the upper left portion of FIG. 12. If the output voltage is within a designated acceptable range, the devices and/or the contacts can be determined to be in proper working order. If the output voltage is not within a designated acceptable range, at least one of the devices and/or at least one of the contacts can be determined to not be in proper working order.

As shown in FIG. 13, the fourth backside contact 387 in the upper left portion of FIG. 13 is serially connected to the fourth backside contact 387 in the upper right portion of FIG. 13 through the first, second and third backside contacts 381, 383 and 385 of the first, second and third backside wiring levels (e.g., first, second and third backside metallization levels M1_{BS}, M2_{BS} and M3_{BS}), the first, second and third vias 382, 384 and 386, the backside source/drain contacts 367, the deep vias 366, the first, second and third BEOL contacts 351, 353 and 355 of the first, second and third frontside wiring level (e.g., first, second and third frontside metallization levels M1_{FS}, M2_{FS} and M3_{FS}), and the first and second vias 352 and 354. As can be understood, the continuous connections extend between the backside and the frontside of the semiconductor structure 300 through the deep vias 366 which connect the backside contacts and the frontside contacts. As can be seen in FIG. 13, all of the contacts (e.g., 350, 351, 253, 355, 381, 383, 385, 387 and vias 352, 354, 366, 382, 384, 386) in the semiconductor structure 300 are serially connected. Respective ones of the first, second, third and fourth backside contacts 381, 383, 385 and 387 of the first, second, third and fourth backside wiring levels and respective first, second and third vias 382, 384 and 386 are physically separated from each other by one or more dielectric layers in the horizontal direction in the cross-sectional views. Respective ones of the first, second and third BEOL contacts 351, 353 and 355 of the first, second and third frontside wiring level and respective first and second vias 352 and 354 are physically separated from each other by one or more dielectric layers in the horizontal direction in the cross-sectional views.

As can be seen in FIG. 13, by virtue of the serial connection of the contacts and devices, an electrical probe contacting the fourth backside contact 387 in the upper left portion of FIG. 13 can apply a voltage to the fourth backside contact 387 in the upper left portion of FIG. 13 to test each of the connected devices (e.g., I, II, III and IV) and generate an output voltage to be read by an electrical probe contacting the fourth backside contact 387 in the upper right portion of FIG. 13. Conversely, by virtue of the serial connection, an electrical probe contacting the fourth backside contact 387 in the upper right portion of FIG. 13 can apply a voltage to the fourth backside contact 387 in the upper right portion of FIG. 13 to test each of the connected devices and generate an output voltage to be read by the electrical probe contacting the fourth backside contact 387 in the upper left portion of FIG. 13. If the output voltage is within a designated acceptable range, the devices and/or the contacts can be determined to be in proper working order. If the output voltage is not within a designated acceptable range, at least one of the devices and/or at least one of the contacts can be determined to not be in proper working order.

According to illustrative embodiments, one or more of the backside wiring levels referenced herein are backside power delivery network (BSPDN) layers (also referred to herein as backside interconnects) with one or more of the backside contacts referenced herein being backside power rails. The BSPDN layers include various BSPDN structures such as, but not necessarily limited to, interconnects in a power supply path from voltage regulator modules (VRMs) to circuits. The interconnects can include, for example, power and ground planes in circuit boards, cables, connectors and capacitors associated with a power supply. Backside power delivery prevents BEOL routing congestion, resulting in power performance benefits.

Although the embodiments depict particular processing steps to form the semiconductor structures 100, 200 and 300, the embodiments are not necessarily limited thereto, and other processing techniques and flows may be used depending on design constraints.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETS, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

As noted above, the embodiments provide techniques and structures for forming semiconductor testing structures. The embodiments provide solutions which allow for periodic electrical testing and monitoring of complex semiconductor builds to detect defects and misprocessing and allow for correction of such defects prior to device completion. The embodiments advantageously provide electrical structures that can be tested in-line for a first electrical function using frontside BEOL levels. The same electrical structures can be tested in-line or off-line for a second electrical function using backside levels. For example, the first function monitors individual structures (see, e.g., FIGS. 3 and 4), while the second function monitors structures in series (see, e.g., FIGS. 10-13).

The illustrative embodiments include testing structures that have metal wiring lines and vias built on sequential layers and aligned in a manner that results in a formation of different test structures that traverse vertically with the BEOL dielectric stack. The first test condition is created early in the semiconductor build, where individual devices can be tested (see, e.g., FIGS. 3 and 4). The individual test structures are then united and connected creating a different second test condition. The joining of the individual test structures into one structure occurs after the addition of a carrier wafer and the structure is flipped. The individual devices are connected/stitched through an active device layer in series creating a new sensor structure. The second test condition is akin to a perimeter line stitch sensor. The larger test structure is configured to sense and monitor above and beneath (e.g., frontside and backside) of the active device region.

In one embodiment, a semiconductor test structure includes a first side, a second side located opposite the first side, and a device layer disposed between the first side and the second side. The device layer includes a plurality of devices. At least one first side wiring level is disposed on the first side, and at least one second side wiring level is disposed on the second side. Two or more of the plurality of devices are electrically connected to each other through at least one contact structure connecting the at least one first side wiring level and the at least one second side wiring level.

The at least one contact structure can be disposed through the device layer between the first side and the second side. The at least one contact structure may include at least one via disposed through the device layer between the first side and the second side. The first side may include a frontside of the semiconductor test structure and the second side includes a backside of the semiconductor test structure. The at least one second side wiring level can include a backside power rail.

The semiconductor test structure may further include at least one dielectric layer, wherein the at least one first side wiring level is disposed in the at least one dielectric layer and includes a plurality of contacts separated from each other by respective portions of the at least one dielectric layer. The respective ones of the plurality of contacts may be electrically connected to each other through a plurality of contact structures connecting the at least one first side wiring level and the at least one second side wiring level, the plurality of contact structures including the at least one contact structure.

The semiconductor test structure may further include at least one dielectric layer, wherein the at least one second side wiring level is disposed in the at least one dielectric layer and includes a plurality of contacts separated from each other by respective portions of the at least one dielectric layer. Respective ones of the plurality of contacts may be electrically connected to each other through a plurality of contact structures connecting the at least one first side wiring level and the at least one second side wiring level, the plurality of contact structures including the at least one contact structure.

The plurality of devices may include a plurality of transistors, wherein the at least one contact structure is disposed through a source/drain region of a transistor of the plurality of transistors. The semiconductor test structure may further include a source/drain contact connecting the at least one first side wiring level to a source/drain region of a transistor of the plurality of transistors. The at least one contact structure may be disposed through an additional source/drain region adjacent the source/drain region of the transistor.

Advantageously, illustrative embodiments provide a multi-level semiconductor test structure with test points at multiple levels, which can be tested during different stages of the wafer build. The semiconductor testing structure includes frontside wiring levels, backside wiring levels and connections that cross active device layer(s) and connect the frontside wiring levels to the backside wiring levels. Early in the build, a testing structure is fabricated which independently tests individual devices. A series connection of individual testing devices is then created to form a macroscopic testing structure later during backside wafer fabrication. Testing points can be located at multiple processing levels including, but not necessarily limited to, frontside metallization, backside metallization, device layer(s) and C4 connections.

In another embodiment, a semiconductor test structure includes a plurality of first side wiring levels disposed on a first side of the semiconductor test structure, and a plurality of second side wiring levels disposed on a second side of the semiconductor test structure. The second side is located opposite the first side. A device layer is disposed between the first side and the second side, wherein the device layer includes a plurality of devices. The plurality of first side wiring levels and the plurality of second side wiring levels are serially connected through a plurality of contact structures. A subset of the plurality of contact structures includes a plurality of vias disposed through the device layer between the first side and the second side.

Two or more of the plurality of devices may be electrically connected to each other through one or more of the plurality of vias. The plurality of devices may include a plurality of transistors, wherein respective ones of the plurality of vias are disposed through respective epitaxial layers of respective transistors of the plurality of transistors.

Portions of respective ones of the plurality of first side wiring levels may be physically separated from each other by at least one dielectric layer on the first side. Portions of respective ones of the plurality of second side wiring levels may be physically separated from each other by at least one dielectric layer on the second side. The first side may include a frontside of the semiconductor test structure and the second side may include a backside of the semiconductor test structure. At least one of the plurality of second side wiring levels may include a backside power rail.

In another embodiment, a semiconductor test structure includes a first plurality of contact structures on a first side of a device layer including a plurality of devices, wherein respective ones of the first plurality of contact structures are connected to respective ones of the plurality of devices. The semiconductor test structure further includes a second plurality of contact structures on a second side of the device layer, wherein the second side of the device layer is located opposite the first side. The first plurality of contact structures are serially connected to the second plurality of contact structures through a plurality of vias disposed through the device layer.

The first side of the device layer may be on a frontside of the semiconductor test structure and the second side of the device layer may be on a backside of the semiconductor test structure. The plurality of devices may include a plurality of transistors, wherein the respective ones of the first plurality of contact structures are connected to respective source/drain regions of the respective ones of the plurality of devices.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor test structure comprising:
a first side;
a second side located opposite the first side;
a device layer disposed between the first side and the second side, wherein the device layer comprises a plurality of devices;
at least one first side wiring level disposed on the first side; and
at least one second side wiring level disposed on the second side;
wherein two or more of the plurality of devices are electrically connected to each other through at least one contact structure connecting the at least one first side wiring level and the at least one second side wiring level.

2. The semiconductor test structure of claim 1, wherein the at least one contact structure is disposed through the device layer between the first side and the second side.

3. The semiconductor test structure of claim 1, wherein the at least one contact structure comprises at least one via disposed through the device layer between the first side and the second side.

4. The semiconductor test structure of claim 1, wherein the first side comprises a frontside of the semiconductor test structure and the second side comprises a backside of the semiconductor test structure.

5. The semiconductor test structure of claim 4, wherein the at least one second side wiring level comprises a backside power rail.

6. The semiconductor test structure of claim 1, further comprising at least one dielectric layer, wherein the at least one first side wiring level is disposed in the at least one dielectric layer and comprises a plurality of contacts separated from each other by respective portions of the at least one dielectric layer.

7. The semiconductor test structure of claim 6, wherein respective ones of the plurality of contacts are electrically connected to each other through a plurality of contact structures connecting the at least one first side wiring level and the at least one second side wiring level, the plurality of contact structures including the at least one contact structure.

8. The semiconductor test structure of claim 1, further comprising at least one dielectric layer, wherein the at least one second side wiring level is disposed in the at least one dielectric layer and comprises a plurality of contacts separated from each other by respective portions of the at least one dielectric layer.

9. The semiconductor test structure of claim 8, wherein respective ones of the plurality of contacts are electrically connected to each other through a plurality of contact structures connecting the at least one first side wiring level and the at least one second side wiring level, the plurality of contact structures including the at least one contact structure.

10. The semiconductor test structure of claim 1, wherein the plurality of devices comprise a plurality of transistors, and wherein the at least one contact structure is disposed through a source/drain region of a transistor of the plurality of transistors.

11. The semiconductor test structure of claim 1, wherein the plurality of devices comprise a plurality of transistors and the semiconductor test structure further comprises a source/drain contact connecting the at least one first side wiring level to a source/drain region of a transistor of the plurality of transistors.

12. The semiconductor test structure of claim 11, wherein the at least one contact structure is disposed through an additional source/drain region adjacent the source/drain region of the transistor.

13. A semiconductor test structure comprising:
a plurality of first side wiring levels disposed on a first side of the semiconductor test structure;
a plurality of second side wiring levels disposed on a second side of the semiconductor test structure, wherein the second side is located opposite the first side; and
a device layer disposed between the first side and the second side, wherein the device layer comprises a plurality of devices;
wherein the plurality of first side wiring levels and the plurality of second side wiring levels are serially connected through a plurality of contact structures; and
wherein a subset of the plurality of contact structures comprises a plurality of vias disposed through the device layer between the first side and the second side.

14. The semiconductor test structure of claim 13, wherein two or more of the plurality of devices are electrically connected to each other through one or more of the plurality of vias.

15. The semiconductor test structure of claim 13, wherein the plurality of devices comprise a plurality of transistors, and wherein respective ones of the plurality of vias are disposed through respective epitaxial layers of respective transistors of the plurality of transistors.

16. The semiconductor test structure of claim 13, wherein:
portions of respective ones of the plurality of first side wiring levels are physically separated from each other by at least one dielectric layer on the first side; and
portions of respective ones of the plurality of second side wiring levels are physically separated from each other by at least one dielectric layer on the second side.

17. The semiconductor test structure of claim 13, wherein:
the first side comprises a frontside of the semiconductor test structure and the second side comprises a backside of the semiconductor test structure; and
at least one of the plurality of second side wiring levels comprises a backside power rail.

18. A semiconductor test structure comprising:
a first plurality of contact structures on a first side of a device layer comprising a plurality of devices, wherein respective ones of the first plurality of contact structures are connected to respective ones of the plurality of devices; and
a second plurality of contact structures on a second side of the device layer;
wherein the second side of the device layer is located opposite the first side; and
wherein the first plurality of contact structures are serially connected to the second plurality of contact structures through a plurality of vias disposed through the device layer.

19. The semiconductor test structure of claim 18, wherein the first side of the device layer is on a frontside of the semiconductor test structure and the second side of the device layer is on a backside of the semiconductor test structure.

20. The semiconductor test structure of claim 18, wherein the plurality of devices comprise a plurality of transistors, and wherein the respective ones of the first plurality of contact structures are connected to respective source/drain regions of the respective ones of the plurality of devices.
